(19) United States
(12) Patent Application Publication
(10) Pub. No.: US 2021/0234129 A1
(43) Pub. Date: Jul. 29, 2021

(54) FLEXIBLE ORGANIC LIGHT EMITTING DIODE DISPLAY PANEL

(71) Applicant: Wuhan China Star Optoelectronics Semiconductor Display Technology Co., LTD., Wuhan (CN)

(72) Inventor: Feng Zhang, Wuhan (CN)

(21) Appl. No.: 16/307,439

(22) PCT Filed: Sep. 13, 2018
(86) PCT No.: PCT/CN2018/105514

§ 371 Date: Dec. 5, 2018

(30) Foreign Application Priority Data
Aug. 30, 2018 (CN) 201811003753.2

(51) Int. Cl. H01L 51/52; H01L 51/00; H01L 27/32

(52) U.S. Cl. CPC H01L 51/5256; H01L 2251/5338; H01L 27/3258; H01L 51/0097

(57) ABSTRACT

A flexible organic light emitting diode (OLED) display panel includes a flexible substrate, a buffer layer, a thin film transistor layer, an OLED light emitting layer, an encapsulation layer. The encapsulation layer includes a first inorganic layer, a first organic layer, a second inorganic layer, and a second organic layer, which are sequentially disposed on the OLED light emitting layer. The first inorganic layer includes a first top surface having at least two protrusions, and the first top surface faces away from the OLED light emitting layer. The second inorganic layer includes a second top surface having at least two protrusions, and the second top surface faces away from the OLED light emitting layer.

### FIELD OF DISCLOSURE

The present disclosure relates to the field of display technologies, and more particularly to a flexible OLED display panel.

### BACKGROUND

Presently, a flexible organic light emitting diode (OLED) display panel is usually formed of inorganic and organic structures in a layer-by-layer manner. The conventional flexible OLED display panel includes a flexible substrate, a barrier layer, a buffer layer, an active layer, a gate insulation layer, a gate, interlayer insulation layer, a source and drain layer, a planarization layer, an OLED light emitting layer, a pixel definition layer, a support pad, an encapsulation layer, etc. The multilayer film structure limits development of the flexible display due to deformation characteristics, and stress of each film material are different. Currently, the flexible display screen is normally called a curved screen because it can only present a fixed curved surface. There is a certain distance from the realization that the flexible screen can be bent and foldable.

In summary, the multilayer film layers of the existing flexible display panel are formed in a layer-by-layer manner, resulting in different stresses on the respective film layers, which limits the development of the display screen in bending and folding.

### SUMMARY OF THE DISCLOSURE

The present disclosure provides a flexible OLED display panel to solve the problem that the stress and deformation of each film layer are different due to the multilayer film structure is formed in a layer-by-layer manner, thereby decreasing a performance of the bending and folding of the display panel.

In order to solve technical problems described above, the technical solution provided by the present disclosure is as follows.

The present disclosure provides a flexible OLED display panel, a display area and a bending area being defined within the flexible OLED display panel, the flexible OLED display panel including: a flexible substrate; a buffer layer formed on the flexible substrate; a thin film transistor layer formed on the buffer layer; an OLED light emitting layer formed on the thin film transistor layer; and an encapsulation layer. The encapsulation layer includes a first inorganic layer, a first organic layer, a second inorganic layer, and a second organic layer, which are sequentially formed on the OLED light emitting layer, The flexible substrate includes a first polyimide layer, a first barrier layer, a second polyimide layer, and a second barrier layer, which are disposed in sequence. The first inorganic layer includes a first top surface having at least two protrusions, the first top surface faces away from the OLED light emitting layer. The second inorganic layer includes a second top surface having at least two protrusions, and the second top surface faces away from the OLED light emitting layer. The first polyimide layer includes a third top surface having at least two protrusions, and the third top surface is adjacent to the first barrier layer. The second polyimide layer includes a fourth top surface having at least two protrusions, and the fourth top surface faces away from the first polyimide layer.

In one embodiment of the present disclosure, the second polyimide layer is located in the bending area and is provided with at least two first through holes, and the second barrier layer contacts with the first barrier layer through the first through holes.

In one embodiment of the present disclosure, the buffer layer includes a first buffer layer and a second buffer layer, which are sequentially disposed on the flexible substrate.

In one embodiment of the present disclosure, the first buffer layer includes a fifth top surface having at least two protrusions, the fifth top surface faces away from the flexible substrate.

In one embodiment of the present disclosure, the first buffer layer is located in the bending area and is provided with at least two second through holes, and the second buffer layer contacts with the flexible substrate through the second through holes.

In one embodiment of the present disclosure, the thin film transistor layer includes a first gate insulation layer, a second gate insulation layer, an interlayer insulation layer, a planarization layer, and a pixel definition layer, which are sequentially disposed on the buffer layer.

In one embodiment of the present disclosure, the second gate insulation layer in the bending area includes a sixth top surface having at least two protrusions, the sixth top surface faces away from the flexible substrate, and the planarization layer is located in the bending area and includes a seventh top surface having at least two protrusions, the seventh top surface faces away from the flexible substrate.

In one embodiment of the present disclosure, the first gate insulation layer is located in the bending area and is provided with at least two third through holes, the second gate insulation layer contacts with the buffer layer through the third through holes, and the interlayer insulation layer is located in the bending area and is provided with at least two fourth through holes, the planarization layer contacts with the second gate insulation layer through the fourth through holes.

The present disclosure also provides a flexible OLED display panel, a display area and a bending area being defined within the flexible OLED display panel, the flexible OLED display panel including: a flexible substrate; a buffer layer formed on the flexible substrate; a thin film transistor layer formed on the buffer layer; an OLED light emitting layer formed on the thin film transistor layer; and an encapsulation layer including a first inorganic layer, a first organic layer, a second inorganic layer, and a second organic layer, which are sequentially formed on the OLED light emitting layer, where the first inorganic layer includes a first top surface having at least two protrusions, the first top surface faces away from the OLED light emitting layer; and the second inorganic layer includes a second top surface having at least two protrusions, and the second top surface faces away from the OLED light emitting layer.

In one embodiment of the present disclosure, the flexible substrate includes a first polyimide layer, a first barrier layer, a second polyimide layer, and a second barrier layer, which are disposed in sequence.

In one embodiment of the present disclosure, the second polyimide layer is located in the bending area and is provided with at least two first through holes, and the second barrier layer contacts with the first barrier layer through the first through holes.

In one embodiment of the present disclosure, the buffer layer includes a first buffer layer and a second buffer layer, which are sequentially disposed on the flexible substrate.

In one embodiment of the present disclosure, the first buffer layer includes a fifth top surface having at least two protrusions, the fifth top surface faces away from the flexible substrate.

In one embodiment of the present disclosure, the first buffer layer is located in the bending area and is provided with at least two second through holes, and the second buffer layer contacts with the flexible substrate through the second through holes.

In one embodiment of the present disclosure, the thin film transistor layer includes a first gate insulation layer, a second gate insulation layer, an interlayer insulation layer, a planarization layer, and a pixel definition layer, which are sequentially disposed on the buffer layer.

In one embodiment of the present disclosure, the second gate insulation layer in the bending area includes a sixth top surface having at least two protrusions, the sixth top surface faces away from the flexible substrate, and the planarization layer is located in the bending area and includes a seventh top surface having at least two protrusions, the seventh top surface faces away from the flexible substrate.

In one embodiment of the present disclosure, the first gate insulation layer is located in the bending area and is provided with at least two third through holes, the second gate insulation layer contacts with the buffer layer through the third through holes, and the interlayer insulation layer is located in the bending area and is provided with at least two fourth through holes, the planarization layer contacts with the second gate insulation layer through the fourth through holes.

The present disclosure has the advantage that by designing the surface of each film layer into a concave-convex structure, the area of each contact surface is increased, thereby eliminating and dispersing the stress generated by each film layer during the bending process, and finally achieving the characteristics of folding and bending of the flexible OLED display panel.

### BRIEF DESCRIPTION OF THE DRAWINGS

In order to more clearly describe the technical solutions of the embodiments of the present disclosure, accompanying drawings to be used in the detailed description of the disclosure will be briefly described hereinbelow. Obviously, the accompanying drawings described hereinbelow only illustrate some of the embodiments of the present disclosure, and those of ordinary skill in the art can also obtain other accompanying drawings therefrom without the need of making inventive efforts.

FIG. 1 is a structural diagram of a flexible OLED display panel of the present disclosure.

FIG. 2 is a structural diagram of an encapsulation layer according to a first embodiment of the present disclosure.

FIG. 3 is a structural diagram of a flexible substrate and a buffer layer in a display area according to a first embodiment of the present disclosure.

FIG. 4 is a structural diagram of a bending area according to a second embodiment of the present disclosure.

FIG. 5 is a structural diagram of a bending area according to a third embodiment of the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

The multilayer film layers of the existing flexible display panel are formed in a layer-by-layer manner and deformation characteristics of the film materials of the respective film layers are different, so the stresses and deformations of the respective film layers are different, thereby decreasing the performance of the bending of the display panel and limiting the development of the display screen. The embodiments of the present disclosure can solve the drawback.

### First Embodiment

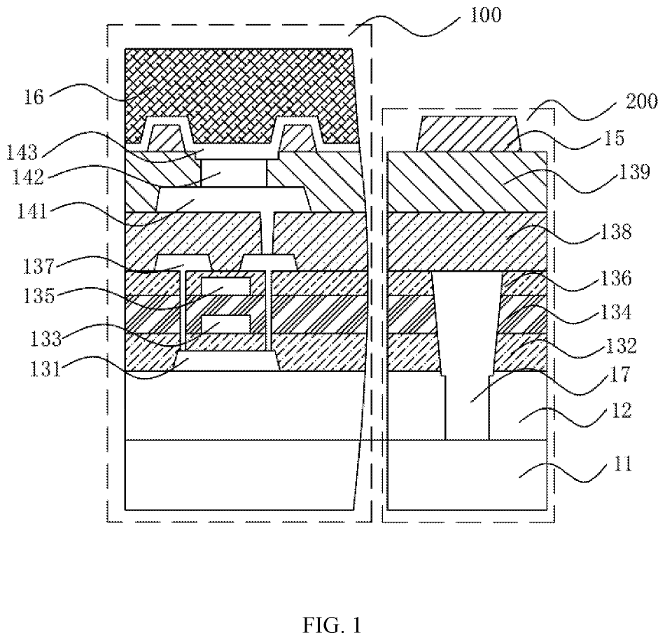

As shown in FIG. 1, this embodiment provides a flexible OLED display panel. A display area 100 and a bending area 200 are defined within the flexible OLED display panel. The flexible OLED display panel includes: a flexible substrate 11, a buffer layer 12 formed on the flexible substrate 11, a thin film transistor layer formed on the buffer layer 12, an OLED light emitting layer 14 formed on the thin film transistor layer, and an encapsulation layer 16 formed on a surface of the OLED light emitting layer 14.

As shown in FIG. 3, the flexible substrate 11 includes a first polyimide layer 111, a first barrier layer 112 disposed on a surface of the first polyimide layer 111, a second polyimide layer 113 disposed on a surface of the first barrier layer 112, and a second barrier layer 114 disposed on a surface of the second polyimide layer 113.

The first polyimide layer 111 is manufactured on a glass substrate (not shown on drawings). After the production is completed, the glass substrate is peeled off. The first polyimide layer 111 includes a third top surface 1111 provided with a plurality of (at least two) protrusions. The third top surface 1111 faces away from the glass substrate, that is, the third top surface 1111 is adjacent to the first barrier layer. The widths of the plurality of protrusions are not consistent, and the separation distances between the protrusions are not consistent.

The first barrier layer 112 is formed on the surface of the first polyimide layer 111. A lower surface of the first barrier layer 112 contacts with the third top surface 1111 of the first polyimide layer 111 to form a concave-convex structure, which increases a contact area between layers. Thus, it is advantageous to disperse and eliminate the stress generated during the bending process.

The second polyimide layer 113 includes a fourth top surface 1131 provided with a plurality of protrusions. The fourth top surface 1131 faces away from the first polyimide layer 111. The second barrier layer 114 is formed on the surface of the second polyimide layer 113. A lower surface of the second barrier layer contacts with the fourth top surface 1131 to form a concave-convex structure.

The flexible substrate 111 adopts a double-layer polyimide structure, thereby providing multiple protection functions to the flexible OLED display panel. Two-layer barrier layer structure prevents water and oxygen from invading and prevents corrosion of OLED devices. The first barrier layer 112 and the second barrier layer 114 are both silicon oxide (SiOx) layers.

The buffer layer 12 includes a first buffer layer 121 disposed on a surface of the second barrier layer 112 and a second buffer layer 122 disposed on a surface of the first buffer layer 121.

The first buffer layer 121 includes a fifth top surface 1211 having a plurality of (at least two) protrusions. The widths of the plurality of protrusions may be the same or different. The distances between the protrusions are not consistent.

A lower surface of the second buffer layer 122 contacts with the fifth top surface 1211 to form a concave-convex structure.

The first buffer layer 121 is a silicon oxide (SiOx) layer, and the second buffer layer 122 is a silicon nitride (SiNx) layer.

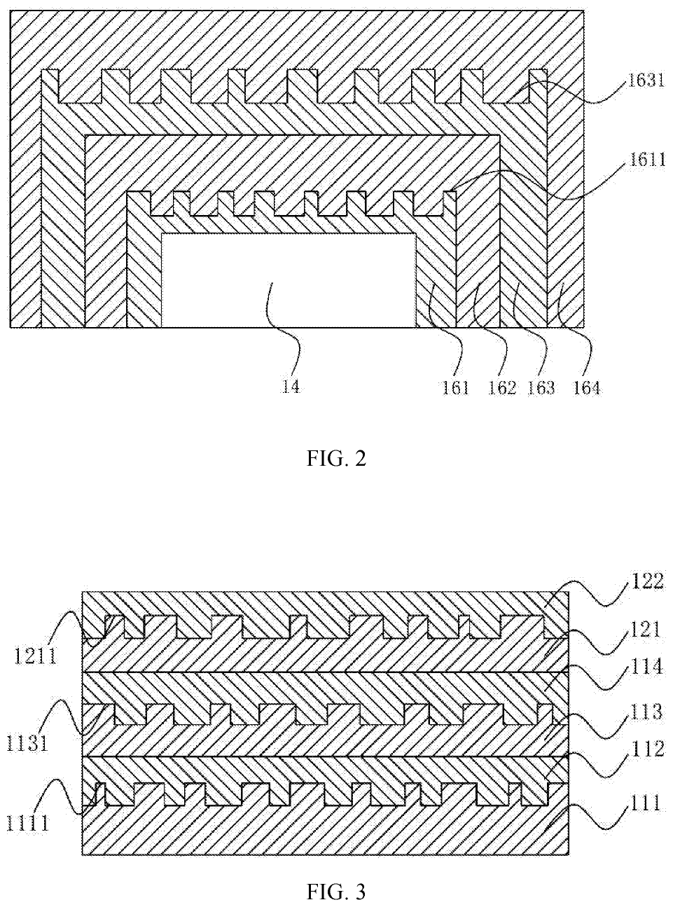

As shown on FIG. 2, the encapsulation layer 16 includes a first inorganic layer 161 disposed on a surface of the OLED light emitting layer 14, a first organic layer 162 disposed on a surface of the first inorganic layer, a second inorganic layer 163 disposed on a surface of the first organic layer 162, and a second organic layer 164 disposed on a surface of the second inorganic layer 163.

The first inorganic layer 161 covers the OLED light emitting layer. The first inorganic layer 161 includes a first top surface 1611 having a plurality of protrusions. The first top surface 1611 faces away from the OLED light emitting layer. The widths of the plurality of protrusions may be the same or different. The separation distances between adjacent protrusions can be the same or different. A lower surface of the first organic layer 162 contacts with the first top surface 1611 to form a concave-convex structure.

The second inorganic layer 163 includes a second top surface 1631 having a plurality of protrusions. The second top surface 1631 faces away from the OLED light emitting layer. A lower surface of the second organic layer 164 contacts with the second top surface 1631 to form a concave-convex structure.

As shown in FIG. 1, the thin film transistor layer includes an active layer 131 disposed on a surface of the second buffer layer 122, a first gate insulation layer 132 disposed on a surface of the active layer 131, where the first gate insulation layer 132 covers the active layer 131, a first gate 133 disposed on a surface of the first gate insulation layer 132, a second gate insulation layer 134 disposed on a surface of the first gate 133, where the second gate insulation layer 134 covers the first gate 133, a second gate 135 disposed on a surface of the second gate insulation layer 134, an interlayer insulation layer 136 disposed on a surface of the second gate 135, where the interlayer insulation layer 136 covers the second gate 135, a source and drain layer 137 disposed on a surface of the interlayer insulation layer 136, a planarization layer 138 disposed on a surface of the source and drain layer 137, and a pixel definition layer 139 formed on the planarization layer 138.

The source and drain layer 137 includes a source and a drain. The second gate insulation layer 134 and the interlayer insulation layer 136 are provided with through holes through which the source or the drain is connected to the active layer. Patterns of the first gate 133 and the second gate 135 are different. The first gate 133 is configured to form the gate, and the second gate 135 is as a metal layer to form a trace or a capacitor.

The planarization layer 138 provides a flat base for the devices in the OLED light emitting layer.

The OLED light emitting layer 14 is disposed in the display area 100. The OLED light emitting layer includes an anode 141 disposed on a surface of the planarization layer 138, a luminescent functional layer 142 disposed on a surface of the anode 141, and a cathode 143 disposed on a surface of the luminescent functional layer 142.

A through hole is disposed on the planarization layer 138, and the anode 141 is electrically connected to the source or drain through the through hole.

The luminescent functional layer 142 a hole injection layer, a hole transport layer, a luminescent material layer, an electron transport layer, and a an electron injection layer, which are disposed in sequence.

The pixel definition layer 139 is provided with a via hole for accommodating a part of the luminescent functional layer, such as a luminescent material layer.

The flexible OLED display panel also includes a support pad 15 which is located on a surface of the pixel definition layer 139. The support pad 15 is used to support a certain height to prevent a mask from contacting the OLED light emitting device during the fabrication of the OLED light emitting layer, thereby causing crush damage to the OLED light emitting device.

The cathode 143 covers a portion of the support pad 15. A surface of the cathode 143 facing away from the first polyimide layer 111 is flush with a surface of the support pad 15 located within the bending area 200 and facing away from the first polyimide layer 111.

The flexible OLED display panel also includes an organic structure layer 17 which is located in the bending area 200 for increasing the flexibility of the extending area 200. A via hole is formed in the second barrier layer 114, the first buffer layer 121, the second buffer layer 122, the first gate insulation layer 132, the second gate insulation layer 134, and the interlayer insulation layer 136 for accommodating the organic structure layer 17.

The bending area 200 has a higher requirement for flexibility with respect to the display area 100, and thus the bending property of the bending area 200 is enhanced by providing the organic structure layer 17.

Although the optimized structure of the film layer in this embodiment is different from the prior art, in the manufacturing process, the process of the photomask process is not increased, and the optimized structure can be realized by simply modifying the mask and the etching process. Therefore, it does not increase the production cost.

### Second Embodiment

In the present embodiment, except for the structure of the thin film transistor layer in the bending area 200 is different from the first embodiment, the other structures are the same as those described in the first embodiment.

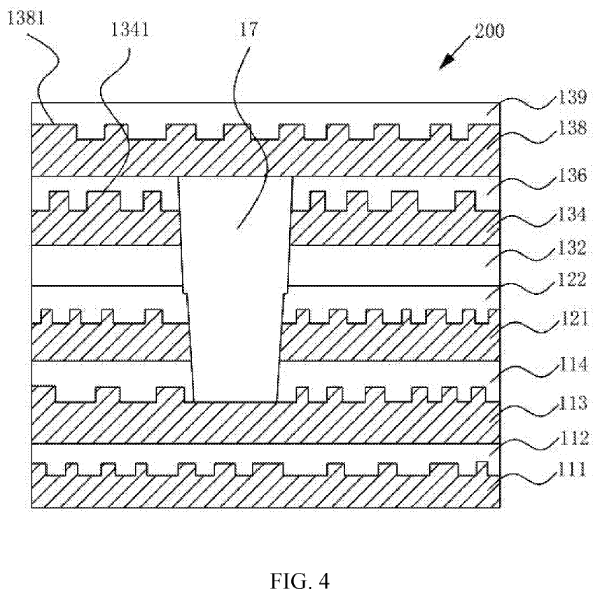

As shown on FIG. 4, in the bending area 200, the second gate insulation layer 134 includes a sixth top surface 1341 having a plurality of protrusions. The sixth top surface 1341 faces away from the flexible substrate 11. A lower surface of the interlayer insulation layer 136 contacts with the sixth top surface 1341 to form a concave-convex structure.

The planarization layer 138 includes a seven top surface 1381 having a plurality of protrusions. The seventh top surface 1381 faces away from the flexible substrate 11. A lower surface of the pixel definition layer 139 contacts with the seventh top surface 1381 to form a concave-convex structure.

In the bending area 200, by providing a plurality of the concave-convex structures and increasing the contact area between the film layers, it is advantageous to eliminate and disperse the stress generated by the film layer during the bending process, and further enhance the bending property of the bending area.

In this embodiment, the distances of adjacent protrusions on each film layer are not consistent, and the widths of the protrusions are not consistent.

### Third Embodiment

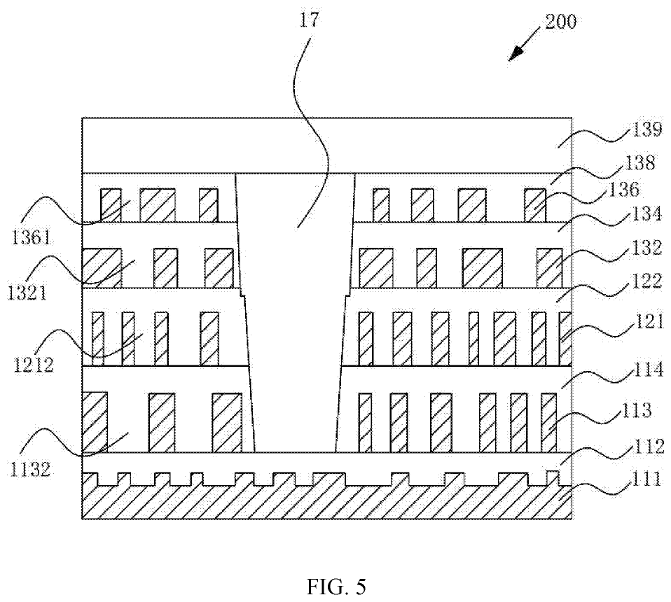

As shown in FIG. 5, on the basis of the second embodiment, part of the film layer is completely removed by a mask in the process of film deposition.

In the bending area 200, the second polyimide layer 113 is provided with a plurality of first through holes 1132, and the second barrier layer 114 contacts with the first barrier layer 112 through the first through holes 1132. In the mask process, a full exposure is employed to form the first through holes 1132.

The first buffer layer 121 is provided with a plurality of second through holes 1212. The second buffer layer 122 contacts with the second barrier layer 114 through the second through holes 1212.

The first gate insulation layer 132 is provided with a plurality of third through holes 1321. The second gate insulation layer 134 contacts with the second buffer layer 122 through the third through holes 1321.

The interlayer insulation layer 136 is provided with a plurality of fourth through holes 1361. The planarization layer 138 contacts with the second gate insulation layer 134 through the fourth through holes 1361.

The through holes in this embodiment have a rectangular cross section. In comparison to other shapes (such as round and oval), the rectangular through hole has a larger contact area, and is easier to fabricate during the manufacturing process.

In comparison to the second embodiment, the present embodiment can also increase the contact area between the layers and disperse the stress by providing a film layer structure having a plurality of through holes.

The present disclosure has the advantage that by designing the surface of each film layer into a concave-convex structure, the area of each contact surface is increased, thereby eliminating and dispersing the stress generated by each film layer during the bending process, and finally achieving the characteristics of folding and bending of the flexible OLED display panel.

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure. Therefore, the protection scope of the present disclosure is subject to the appended claims.

What is claimed is:

1. A flexible organic light emitting diode (OLED) display panel, a display area and a bending area being defined within the flexible OLED display panel, the flexible OLED display panel, comprising:
a flexible substrate comprising a first polyimide layer, a first barrier layer, a second polyimide layer, and a second barrier layer, which are disposed in sequence;
a buffer layer formed on the flexible substrate;
a thin film transistor layer formed on the buffer layer;
an OLED light emitting layer formed on the thin film transistor layer; and
an encapsulation layer comprising a first inorganic layer, a first organic layer, a second inorganic layer, and a second organic layer, which are sequentially formed on the OLED light emitting layer,
wherein the first inorganic layer comprises a first top surface having at least two protrusions, the first top surface faces away from the OLED light emitting layer, the second inorganic layer comprises a second top surface having at least two protrusions, and the second top surface faces away from the OLED light emitting layer;
the first polyimide layer comprises a third top surface having at least two protrusions, and the third top surface is adjacent to the first barrier layer; and
the second polyimide layer comprises a fourth top surface having at least two protrusions, and the fourth top surface faces away from the first polyimide layer.

2. The flexible OLED display panel as claimed in claim 1, wherein the second polyimide layer is located in the bending area and is provided with at least two first through holes, and the second barrier layer contacts with the first barrier layer through the first through holes.

3. The flexible OLED display panel as claimed in claim 1, wherein the buffer layer comprises a first buffer layer and a second buffer layer, which are sequentially disposed on the flexible substrate.

4. The flexible OLED display panel as claimed in claim 3, wherein the first buffer layer comprises a fifth top surface having at least two protrusions, the fifth top surface faces away from the flexible substrate.

5. The flexible OLED display panel as claimed in claim 3, wherein the first buffer layer is located in the bending area and is provided with at least two second through holes, and the second buffer layer contacts with the flexible substrate through the second through holes.

6. The flexible OLED display panel as claimed in claim 1, wherein the thin film transistor layer comprises a first gate insulation layer, a second gate insulation layer, an interlayer insulation layer, a planarization layer, and a pixel definition layer, which are sequentially disposed on the buffer layer.

7. The flexible OLED display panel as claimed in claim 6, wherein the second gate insulation layer in the bending area comprises a sixth top surface having at least two protrusions, the sixth top surface faces away from the flexible substrate, and the planarization layer is located in the bending area and comprises a seventh top surface having at least two protrusions, the seventh top surface faces away from the flexible substrate.

8. The flexible OLED display panel as claimed in claim 6, wherein the first gate insulation layer is located in the bending area and is provided with at least two third through holes, the second gate insulation layer contacts with the buffer layer through the third through holes, and the interlayer insulation layer is located in the bending area and is provided with at least two fourth through holes, the planarization layer contacts with the second gate insulation layer through the fourth through holes.

9. A flexible organic light emitting diode (OLED) display panel, a display area and a bending area being defined within the flexible OLED display panel, the flexible OLED display panel comprising:
a flexible substrate;
a buffer layer formed on the flexible substrate;
a thin film transistor layer formed on the buffer layer;
an OLED light emitting layer formed on the thin film transistor layer; and
an encapsulation layer comprising a first inorganic layer, a first organic layer, a second inorganic layer, and a second organic layer, which are sequentially formed on the OLED light emitting layer,
wherein the first inorganic layer comprises a first top surface having at least two protrusions, the first top surface faces away from the OLED light emitting layer; and
the second inorganic layer comprises a second top surface having at least two protrusions, and the second top surface faces away from the OLED light emitting layer.

10. The flexible OLED display panel as claimed in claim 9, wherein the flexible substrate comprises a first polyimide layer, a first barrier layer, a second polyimide layer, and a second barrier layer, which are disposed in sequence.

11. The flexible OLED display panel as claimed in claim 10, wherein the second polyimide layer is located in the bending area and is provided with at least two first through holes, and the second barrier layer contacts with the first barrier layer through the first through holes.

12. The flexible OLED display panel as claimed in claim 9, wherein the buffer layer comprises a first buffer layer and a second buffer layer, which are sequentially disposed on the flexible substrate.

13. The flexible OLED display panel as claimed in claim 12, wherein the first buffer layer comprises a fifth top surface having at least two protrusions, the fifth top surface faces away from the flexible substrate.

14. The flexible OLED display panel as claimed in claim 12, wherein the first buffer layer is located in the bending area and is provided with at least two second through holes, and the second buffer layer contacts with the flexible substrate through the second through holes.

15. The flexible OLED display panel as claimed in claim 14, wherein the thin film transistor layer comprises a first gate insulation layer, a second gate insulation layer, an interlayer insulation layer, a planarization layer, and a pixel definition layer, which are sequentially disposed on the buffer layer.

16. The flexible OLED display panel as claimed in claim 15, wherein the second gate insulation layer in the bending area comprises a sixth top surface having at least two protrusions, the sixth top surface faces away from the flexible substrate, and the planarization layer is located in the bending area and comprises a seventh top surface having at least two protrusions, the seventh top surface faces away from the flexible substrate.

17. The flexible OLED display panel as claimed in claim 15, wherein the first gate insulation layer is located in the bending area and is provided with at least two third through holes, the second gate insulation layer contacts with the buffer layer through the third through holes, and the interlayer insulation layer is located in the bending area and is provided with at least two fourth through holes, the planarization layer contacts with the second gate insulation layer through the fourth through holes.
